(19) United States
(12) Patent Application Publication
(10) Pub. No.: US 2026/0369340 A1
(43) Pub. Date: Nov. 19, 2026

(54) MEMORY DEVICE AND MEMORY SYSTEM CONFIGURED TO GENERATE AN INTERNAL CLOCK SIGNAL

(71) Applicant: SK hynix Inc., Icheon-si Gyeonggi-do (KR)

(72) Inventors: Min Kyu MOON, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/325,132

(22) Filed: Sep. 10, 2025

(30) Foreign Application Priority Data
May 15, 2025 (KR) 10-2025-0063532

(51) Int. Cl. G11C 29/12; G11C 29/02; G11C 29/14

(52) U.S. Cl. CPC G11C 29/12015; G11C 29/028; G11C 29/14

(57) ABSTRACT

A memory device includes a calibration code generation circuit configured to generate a calibration code based on a calibration test mode signal and a calibrated clock signal, a transmission code generation circuit configured to shift the calibration code based on a shifting test mode signal to generate a shifting code, encode the shifting code to generate an encoding code, and generate and transmit a transmission code based on the encoding code, and a clock calibration circuit configured to calibrate a clock signal according to a selected calibration code generated based on the calibration code to generate a calibrated clock signal.

### CROSS-REFERENCE TO RELATED APPLICATIONS

The present application claims priority under 35 U.S.C § 119(a) to Korean Patent Application No. 10-2025-0063532, filed in the Korean Intellectual Property Office on May 15, 2025, the entire contents of which application is incorporated herein by reference.

### BACKGROUND

### 1. Technical Field

The present disclosure generally relates to a memory device and memory system, and more particularly, to a memory device and memory system configured to generate an internal clock signal.

### 2. Related Art

Stack memory systems such as high bandwidth memory (HBM) devices are used in a wide range of applications due to their high bandwidth and energy efficiency. Unlike conventional memory systems that use parallel data buses, the stack memory system includes a stack memory device including a base die and a plurality of core dies interconnected by through silicon vias (TSVs). The stack memory device includes a physical interface, such as a physical layer for communication with a processor. The physical layer is designed for high-speed data transmission and efficient communication.

### SUMMARY

The present disclosure provides a memory device that may include a calibration code generation circuit configured to generate a calibration code based on a calibration test mode signal and a calibrated clock signal, a transmission code generation circuit configured to shift the calibration code based on a shifting test mode signal to generate a shifting code, encode the shifting code to generate an encoding code, and generate and transmit a transmission code based on the encoding code, and a clock calibration circuit configured to calibrate a clock signal according to a selected calibration code generated based on the calibration code to generate a calibrated clock signal.

The present disclosure provides a memory system that may include a base die and a plurality of core dies disposed over an interposer. In the present disclosure, the base die may include a first alignment circuit configured to generate a calibration code based on a calibration test mode signal and a calibrated clock signal, shift the calibration code based on a shifting test mode signal to generate a shifting code, encode the shifting code to generate an encoding code, and generate and transmit a transmission code based on the encoding code, and a second alignment circuit configured to decode the transmission code to generate a decoded code, and calibrate a strobe signal based on the decoded code to generate a calibrated strobe signal.

The present disclosure describes a memory system that may be configured be stacking a plurality of dies. In the present disclosure, the one of the plurality of dies may include a physical layer configured to control transmission of data, commands, and addresses using a plurality of channels between core dies and a processor, and a serial-to-parallel conversion circuit configured to convert serial signals transmitted serially through the physical layer into parallel signals, align the parallel signals through a plurality of alignment circuits, and transmit the aligned parallel signals to a through via region. In the present disclosure, the plurality of alignment circuits may include a first alignment circuit and a second alignment circuit. In the present disclosure, the first alignment circuit may be configured to generate a calibration code based on a calibration test mode signal and a calibrated clock signal, shift the calibration code based on a shifting test mode signal to generate a shifting code, encode the shifting code to generate an encoding code, and generate and transmit a transmission code based on the encoding code. In the present disclosure, the second alignment circuit may be configured to decode the transmission code to generate a decoded code, and calibrate a strobe signal based on the decoded code to generate a calibrated strobe signal.

### BRIEF DESCRIPTION OF THE DRAWINGS

FIG. 1 illustrates alignment circuits according to an embodiment of the present disclosure.

FIG. 2 illustrates a calibration code generation circuit according to an embodiment of the present disclosure.

FIG. 3 illustrates a synthetic test strobe signal generation circuit according to an embodiment of the present disclosure.

FIG. 4 illustrates a strobe signal synthesis circuit according to an embodiment of the present disclosure.

FIG. 5 is a timing diagram during an operation of a strobe signal synthesis circuit according to an embodiment of the present disclosure.

FIG. 6 illustrates a strobe signal comparison circuit according to an embodiment of the present disclosure.

FIG. 7 is a timing diagram during an operation of a strobe signal comparison circuit according to an embodiment of the present disclosure.

FIGS. 8, 9, and 10 are tables during an operation of a code shifting circuit according to an embodiment of the present disclosure.

FIG. 11 and FIG. 12 are tables during an operation of a code encoder according to an embodiment of the present disclosure.

FIG. 13 and FIG. 14 are tables during an operation of a code decoder according to an embodiment of the present disclosure.

FIG. 15 illustrates a base die according to an embodiment of the present disclosure.

FIG. 16 illustrates a memory system according to an embodiment of the present disclosure.

### DETAILED DESCRIPTION

In the following description of embodiments, when a parameter is referred to as being “preset” or “predetermined,” it may be intended to mean that a value of the parameter is determined in advance when the parameter is used in a process or an algorithm. The value of the parameter may be set when the process or the algorithm starts or may be set during a period in which the process or the algorithm is executed. For example, a preset clock delay period or preset pulse width means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

The term “binary bit set” may mean a combination of logic levels of bits included in a signal. The binary bit set of the signal may be set differently when a logic level of each bit included in the signal is changed.

Embodiments of the present disclosure are described with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

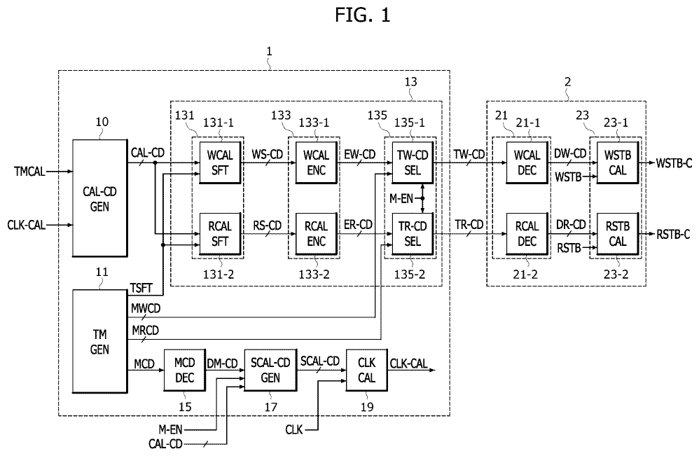

FIG. 1 illustrates a first alignment circuit 1 and a second alignment circuit 2 according to an embodiment of the present disclosure. The first alignment circuit 1 may be implemented as a command address alignment circuit, and the second alignment circuit 2 may be implemented as a data alignment circuit. However, this is only an example, and the present disclosure is not limited to the example.

As shown in FIG. 1, the first alignment circuit 1 includes a calibration code generation circuit (CAL-CD GEN) 10, a test mode signal generation circuit (TM GEN) 11, a transmission code generation circuit 13, a manual code decoder (MCD DEC) 15, a selected calibration code generation circuit (SCAL-CD GEN) 17, and a clock calibration circuit (CLK CAL) 19.

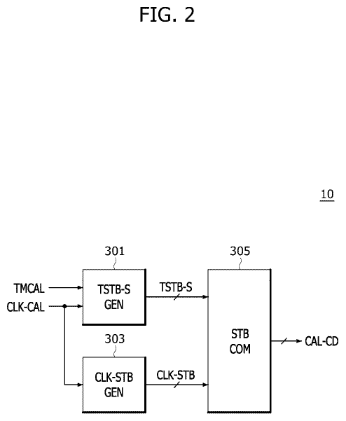

The calibration code generation circuit 10 generates a calibration code CAL-CD based on a calibration test mode signal TMCAL and a calibrated clock signal CLK-CAL. The calibration code generation circuit 10 generates a synthetic test strobe signal, for example, a synthetic test strobe signal TSTB-S in FIG. 2 and a clock strobe signal, for example, a clock strobe signal CLK-STB in FIG. 2, based on the calibration test mode signal TMCAL and the calibrated clock signal CLK-CAL, and compares the synthesis test strobe signal with the clock strobe signal to generate the calibration code CAL-CD. The calibration test mode signal TMCAL is a test mode signal activated for a calibration test operation. The calibration test operation is performed to calibrate internal clock signals ICLK, QCLK, ICLKB, and QCLKB. Whether the calibration test mode signal TMCAL is activated may be adjusted by a command and an address in an initialization operation of a mode register set or the like. The calibration code generation circuit 10 generates the calibration code CAL-CD having a bit set corresponding to a difference in a delay period in order to calibrate the difference in the delay period between the strobe signal and a path through which the clock signal is transmitted.

The test mode signal generation circuit 11 generates and outputs a shifting test mode signal TSFT, a manual read code MRCD, a manual write code MWCD, and a manual code MCD for a test mode operation. The test mode signal generation circuit 11 sets and stores the shifting test mode signal TSFT, the manual read code MRCD, the manual write code MWCD, and the manual code MCD based on a command and an address in an initialization operation such as a mode register set.

The transmission code generation circuit 13 is electrically connected to the calibration code generation circuit 10 and the test mode signal generation circuit 11, receives the calibration code CAL-CD from the calibration code generation circuit 10, and receives the shifting test mode signal TSFT, the manual read code MRCD, and the manual write code MWCD from the test mode signal generation circuit 11. The transmission code generation circuit 13 shifts the calibration code CAL-CD based on the shifting test mode signal TSFT to generate a write shifting code WS-CD and a read shifting code RS-CD. The transmission code generation circuit 13 encodes the write shifting code WS-CD and the read shifting code RS-CD to generate an encoding write code EW-CD and an encoding read code ER-CD. The transmission code generation circuit 13 generates a transmission write code TW-CD and a transmission read code TR-CD from the encoding write code EW-CD, the encoding read code ER-CD, the manual write code MWCD, and the manual read code MRCD based on a manual activation signal M-EN. The manual activation signal M-EN may be activated to select the manual write code MWCD, the manual read code MRCD, and the manual code MCD. The transmission code generation circuit 13 includes a code shifting circuit 131, a code encoder 133, and a transmission code selection circuit 135.

The code shifting circuit 131 includes a write code shifting circuit 131-1 and a read code shifting circuit 131-2. The write code shifting circuit 131-1 shifts the calibration code CAL-CD based on the shifting test mode signal TSFT to generate the write shifting code WS-CD. The read code shifting circuit 131-2 shifts the calibration code CAL-CD based on the shifting test mode signal TSFT to generate the read shifting code RS-CD. The shifting test mode signal TSFT is set to have a binary bit set according to a shifting level. For example, when the shifting level is −2, the shifting test mode signal TSFT is set to have a binary bit set of “LL”. As another example, when the shifting level is 1, the shifting test mode signal TSFT is set to have a binary bit set of “HL”.

The write code shifting circuit 131-1 shifts the calibration code CAL-CD by the shifting level of the shifting test mode signal TSFT to generate the write shifting code WS-CD. For example, when the shifting level is set to −2 and the shifting test mode signal TSFT having a binary bit set of “LL” is received, the write code shifting circuit 131-1 shifts the calibration code CAL-CD<0:6> having a binary bit set of “HHHLLL” so that the number of bits set to “H” is reduced by 2 and generates a write shifting code WS-CD<0:6> having a binary bit set of “HLLLLL.”

The read code shifting circuit 131-2 shifts the calibration code CAL-CD by the shifting level of the shifting test mode signal TSFT to generate the read shifting code RS-CD. For example, when the shifting level is set to 1 and the shifting test mode signal TSFT having a binary bit set of “HL” is received, the read code shifting circuit 131-2 shifts the calibration code CAL-CD<0:6> having a binary bit set of “HHHLLLL” so that the number of bits set to “H” is increased by 1 to generate the read shifting code RS-CD<0:6> having a binary bit set of “HHHHLLL”.

The code encoder 133 includes a write code encoder 133-1 and a read code encoder 133-2.

The write code encoder 133-1 is electrically connected to the write code shifting circuit 131-1 and receives the write shifting code WS-CD from the write code shifting circuit 131-1. The write code encoder 133-1 encodes the write shifting code WS-CD to generate the encoding write code EW-CD. The write code encoder 133-1 encodes the write shifting code WS-CD to generate the encoding write code EW-CD including fewer bits than the bits included in the write shifting code WS-CD. For example, the write code encoder 133-1 encodes the write shifting code WS-CD having a binary bit set of 8 bits to generate the encoding write code EW-CD having a binary bit set of 3 bits.

The read code encoder 133-2 is electrically connected to the read code shifting circuit 131-2 and receives the read shifting code RS-CD from the read code shifting circuit 131-2. The read code encoder 133-2 encodes the read shifting code RS-CD to generate the encoding read code ER-CD. The read code encoder 133-2 encodes the read shifting code RS-CD to generate the encoding read code ER-CD including fewer bits the bits included in the read shifting code RS-CD. For example, the read code encoder 133-2 encodes the read shifting code RS-CD having a binary bit set of 8 bits to generate the encoding read code ER-CD having a binary bit set of 3 bits.

The transmission code selection circuit 135 includes a write transmission code selection circuit 135-1 and a read transmission code selection circuit 135-2.

The write transmission code selection circuit 135-1 is electrically connected to the test signal generation circuit 11 and the write code encoder 133-1, receives the manual write code MWCD from the test mode signal generation circuit 11, and receives the encoding write code EW-CD from the write code encoder 133-1. The write transmission code selection circuit 135-1 generates the transmission write code TW-CD from the encoding write code EW-CD and the manual write code MWCD based on the manual activation signal M-EN. The write transmission code selection circuit 135-1 selects and outputs the encoding write code EW-CD as the transmission write code TW-CD when the manual activation signal M-EN is deactivated, and selects and outputs the manual write code MWCD as the transmission write code TW-CD when the manual activation signal M-EN is activated.

The read transmission code selection circuit 135-2 is electrically connected to the test mode signal generation circuit 11 and the read code encoder 133-2, receives the manual read code MRCD from the test mode signal generation circuit 11, and receives the encoding read code ER-CD from the read code encoder 133-2. The read transmission code selection circuit 135-2 generates the transmission read code TR-CD from the encoding read code ER-CD and the manual read code MRCD based on the manual activation signal M-EN. The read transmission code selection circuit 135-2 selects and outputs the encoding read code ER-CD as the transmission read code TR-CD when the manual activation signal M-EN is deactivated, and selects and outputs the manual read code MRCD as the transmission read code TR-CD when the manual activation signal M-EN is activated.

The manual code decoder 15 is electrically connected to the test mode signal generation circuit 11 and receives the manual code MCD from the test mode signal generation circuit 11. The manual code decoder 15 decodes the manual code MCD to generate a decoding manual code DM-CD including the same number of bits as the calibration code CAL-CD.

The selected calibration code generation circuit 17 is electrically connected to the calibration code generation circuit 10 and the manual code decoder 15, receives the calibration code CAL-CD from the calibration code generation circuit 10, and receives the decoding manual code DM-CD from the manual code decoder 15. The selected calibration code generation circuit 17 generates the selected calibration code SCAL-CD from the calibration code CAL-CD and the decoding manual code DM-CD based on the manual activation signal M-EN. The selected calibration code generation circuit 17 selects and outputs the calibration code CAL-CD as the selected calibration code SCAL-CD when the manual activation signal M-EN is activated, and selects and outputs the decoding manual code DM-CD as the selected calibration code SCAL-CD when the manual activation signal M-EN is deactivated.

The clock calibration circuit 19 is electrically connected to the selected calibration code generation circuit 17 and receives the selected calibration code SCAL-CD from the selected calibration code generation circuit 17. The clock calibration circuit 19 calibrates a clock signal CLK based on the selected calibration code SCAL-CD to generate the calibrated clock signal CLK-CAL. The clock calibration circuit 19 delays the clock signal CLK by a calibration delay period set by the selected calibration code SCAL-CD to generate the calibrated clock signal CLK-CAL.

As shown in FIG. 1, the second alignment circuit 2 is electrically connected to the first alignment circuit 1 and receives the transmission write code TW-CD and the transmission read code TR-CD from the first alignment circuit 1. The second alignment circuit 2 decodes the transmission write code TW-CD and the transmission read code TR-CD to generate the decoded write code DW-CD and the decoded read code DR-CD. The second alignment circuit 2 calibrates a write strobe signal WSTB and a read strobe signal RSTB based on the decoded write code DW-CD and the decoded read code DR-CD to generate a calibrated write strobe signal WSTB-C and a calibrated read strobe signal RSTB-C.

The code decoder 21 includes a write code decoder 21-1 and a read code decoder 21-2.

The write code decoder 21-1 decodes the transmission write code TW-CD to generate the decoded write code DW-CD. The write code decoder 21-1 decodes the transmission write code TW-CD to generate the decoded write code DW-CD including the same number of bits as the calibration code CAL-CD. For example, when the calibration code CAL-CD has a binary bit set of 8 bits, the write code decoder 21-1 decodes the transmission write code TW-CD having a binary bit set of 3 bits to generate the decoded write code DW-CD having a binary bit set of 8 bits.

The read code decoder 21-2 decodes the transmission read code TR-CD to generate the decoded read code DR-CD. The read code decoder 21-2 decodes the transmission read code TR-CD to generate the decoded read code DR-CD including the same number of bits as the calibration code CAL-CD. For example, when the calibration code CAL-CD has a binary bit set of 8 bits, the read code decoder 21-2 decodes the transmission read code TR-CD having a binary bit set of 3 bits to generate the decoded read code DR-CD having a binary bit set of 8 bits.

The strobe signal calibration circuit 23 includes a write strobe signal calibration circuit 23-1 and a read strobe signal calibration circuit 23-2.

The write strobe signal calibration circuit 23-1 is electrically connected to the write code decoder 21-1 and receives the decoded write code DW-CD from the write code decoder 21-1. The write strobe signal calibration circuit 23-1 calibrates the write strobe signal WSTB based on the decoded write code DW-CD to generate the calibrated write strobe signal WSTB-C. The write strobe signal calibration circuit 23-1 delays the write strobe signal WSTB by a write calibration delay period set by the decoded write code DW-CD to generate the calibrated write strobe signal WSTB-C.

The read strobe signal calibration circuit 23-2 is electrically connected to the read code decoder 21-2 and receives the decoded read code DR-CD from the read code decoder 21-2. The read strobe signal calibration circuit 23-2 calibrates the read strobe signal RSTB based on the decoded read code DR-CD to generate the calibrated read strobe signal RSTB-C. The read strobe signal calibration circuit 23-2 delays the read strobe signal RSTB by a read calibration delay period set by the decoded read code DR-CD to generate the calibrated read strobe signal RSTB-C.

FIG. 2 illustrates a calibration code generation circuit 10 according to an embodiment of the present disclosure, for example, as shown in FIG. 1.

As shown in FIG. 2, the calibration code generation circuit 10 includes a synthetic test strobe signal generation circuit (TSTB-S GEN) 301, a clock strobe signal generation circuit (CLK-STB GEN) 303, and a strobe signal comparison circuit (STB COM) 305.

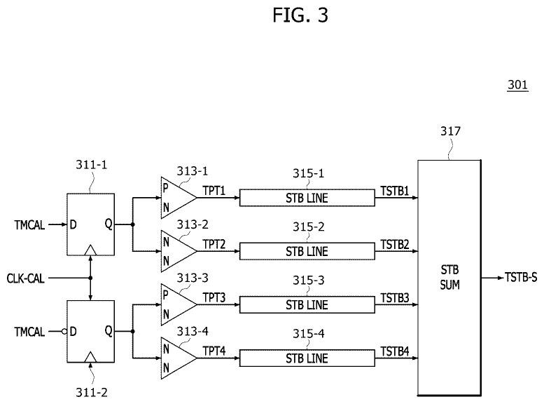

The synthetic test strobe signal generation circuit 301 generates a synthetic test strobe signal TSTB-S based on a calibration test mode signal TMCAL and a calibrated clock signal CLK-CAL. The synthetic test strobe signal generation circuit 301 latches the calibration test mode signal TMCAL based on the calibrated clock signal CLK-CAL to generate a plurality of test patterns, for example, test patterns TPT1, TPT2, TPT3, and TPT4 of FIG. 3, and synthesizes the plurality of test patterns to generate the synthetic test strobe signal TSTB-S. The plurality of test patterns may be set to transition from a logic low level to a logic high level or transition from a logic high level to a logic low level, and may be driven by a plurality of drivers having different driving forces, for example, PN drivers and NN drivers in FIG. 3. The synthetic test strobe signal generation circuit 301 transmits the plurality of test patterns to the strobe line of each of the plurality of test patterns to generate a plurality of test strobe signals, and synthesizes the plurality of test strobe signals to generate the synthetic test strobe signal TSTB-S. The synthetic test strobe signal generation circuit 301 generates the synthetic test strobe signal TSTB-S having logic level transitions in synchronization with a latest point in time among the points in time at which the logic levels of the plurality of test strobe signals transition.

The clock strobe signal generation circuit 303 generates a clock strobe signal CLK-STB based on the calibration test mode signal TMCAL and the calibrated clock signal CLK-CAL. The clock strobe signal generation circuit 303 delays the calibrated clock signal CLK-CAL by a preset clock delay period when the calibration test mode signal TMCAL is activated to generate a delayed calibrated clock signal (not shown) and generates the clock strobe signal CLK-STB in synchronization with the delayed calibrated clock signal. The clock delay period may be determined depending on a clock driver (not shown) that drives the calibrated clock signal CLK-CAL and a clock transmission line (not shown) through which the calibrated clock signal CLK-CAL is transmitted. The clock strobe signal generation circuit 303 generates the clock strobe signal CLK-STB generated as a pulse in synchronization with a first rising edge of the delayed calibrated clock signal when the calibration test mode signal TMCAL is activated. The clock strobe signal CLK-STB may be generated as a pulse having a preset pulse width from a point in time when the first rising edge of the delayed calibrated clock signal is generated.

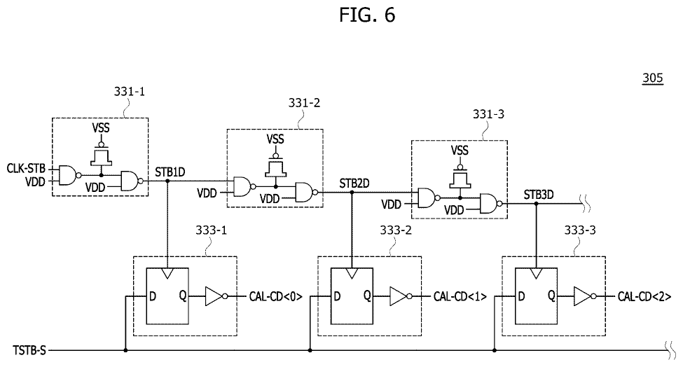

The strobe signal comparison circuit 305 is electrically connected to the synthetic test strobe signal generation circuit 301 and the clock strobe signal generation circuit 303, receives the synthetic test strobe signal TSTB-S from the synthetic test strobe signal generation circuit 301, and receives the clock strobe signal CLK-STB from the clock strobe signal generation circuit 303. The strobe signal comparison circuit 305 generates the calibration code CAL-CD based on the synthetic test strobe signal TSTB-S and the clock strobe signal CLK-STB. The strobe signal comparison circuit 305 sequentially delays the clock strobe signal CLK-STB by a unit delay period to generate a plurality of delayed strobe signals, for example, delayed strobe signals STB1D, STB2D, and STB3D in FIG. 6, and latches the synthetic test strobe signal TSTB-S in synchronization with each of the plurality of delayed strobe signals to generate the calibration code CAL-CD. The strobe signal comparison circuit 305 generates the calibration code CAL-CD including bits having logic levels that are determined according to the logic level of the synthetic test strobe signal TSTB-S latched in synchronization with each of the plurality of delayed strobe signals.

FIG. 3 illustrates a synthetic test strobe signal generation circuit 301 according to an embodiment of the present disclosure, for example, as shown in FIG. 2.

As shown in FIG. 3, the synthetic test strobe signal generation circuit 301 includes a first test input latch 311-1, a second test input latch 311-2, a first test driver 313-1, a second test driver 313-2, a third test driver 313-3, a fourth test driver 313-4, a first strobe line 315-1, a second strobe line 315-2, a third strobe line 315-3, a fourth strobe line 315-4, and a strobe signal synthesis circuit (STB SUM) 317.

The first test input latch 311-1 latches and outputs a calibration test mode signal TMCAL based on a calibrated clock signal CLK-CAL. The first test input latch 311-1 latches and outputs the calibration test mode signal TMCAL in synchronization with a rising edge of the calibrated clock signal CLK-CAL. The first test input latch 311-1 generates a signal having a logic level that transitions from a logic low level to a logic high level at a point in time when the rising edge of the calibrated clock signal CLK-CAL occurs.

The second test input latch 311-2 latches and outputs an inverted signal of the calibration test mode signal TMCAL based on the calibrated clock signal CLK-CAL. The second test input latch 311-2 latches and outputs the inverted signal of the calibration test mode signal TMCAL in synchronization with the rising edge of the calibrated clock signal CLK-CAL. The second test input latch 311-2 generates a signal having a logic level that transitions from a logic high level to a logic low level at the point in time when the rising edge of the calibrated clock signal CLK-CAL occurs.

The first test driver 313-1 is electrically connected to the first test input latch 311-1 and receives the signal having a logic level that transitions from a logic low level to a logic high level from the first test input latch 311-1 at the point in time when the rising edge of the calibration clock CLK-C occurs. The first test driver 313-1 drives a first test pattern TPT1 based on the output signal of the first test input latch 111-1. The first test driver 313-1 may be implemented as a PN driver in which a PMOS transistor and an NMOS transistor are coupled in a CMOS structure. The PN driver pulls up the first test pattern TPT1 to a power supply voltage VDD by the PMOS transistor and drives the first test pattern TPT1 to a ground voltage VSS by the NMOS transistor. The PN driver drives the first test pattern TPT1 to the ground voltage VSS, and then drives the first test pattern TPT1 to the power supply voltage VDD.

The second test driver 313-2 is electrically connected to the first test input latch 311-1 and receives the signal having a logic level that transitions from a logic low level to a logic high level from the first test input latch 311-1 at the point in time when the rising edge of the calibrated clock signal CLK-CAL occurs. The second test driver 313-2 drives a second test pattern TPT2 based on the output signal of the first test input latch 311-1. The second test driver 313-2 may be implemented as an NN driver using only NMOS transistors. The NN driver pulls up the second test pattern TPT2 to (power supply voltage VDD-threshold voltage Vₜₕ) by the NMOS transistor, and drives the second test pattern TPT2 to the ground voltage VSS by the NMOS transistor. The NN driver drives the second test pattern TPT2 to the ground voltage VSS, and then drives the second test pattern TPT2 to the (power supply voltage VDD-threshold voltage Vₜₕ). The NN driver consumes more power than the PN driver, but has greater driving power and can perform higher-speed operations than the PN driver.

The third test driver 313-3 is electrically connected to the second test input latch 311-2 and receives the signal having a logic level that transitions from a logic high level to a logic low level from the second test input latch 311-2 at a point in time when the rising edge of the calibration clock CLK-C occurs. The third test driver 313-3 drives a third test pattern TPT3 based on the output signal of the second test input latch 311-2. The third test driver 313-3 may be implemented as a PN driver in which PMOS transistors and NMOS transistors are coupled in the CMOS structure. The PN driver pulls up the third test pattern TPT3 to the power supply voltage VDD by the PMOS transistor and drives the third test pattern TPT3 to the ground voltage VSS by the NMOS transistor. The PN driver drives the third test pattern TPT3 to the ground voltage VSS, and then drives the third test pattern TPT3 to the power supply voltage VDD.

The fourth test driver 313-4 is electrically connected to the second test input latch 311-2 and receives the signal having a logic level that transitions from a logic high level to a logic low level from the second test input latch 311-2 at a point in time when the rising edge of the calibrated clock signal CLK-CAL occurs. The fourth test driver 313-4 drives a fourth test pattern TPT4 based on the output signal of the second test input latch 311-2. The fourth test driver 313-4 may be implemented as an NN driver using only NMOS transistors. The NN driver pulls up the fourth test pattern TPT4 to (power supply voltage VDD-threshold voltage Vₜₕ) by the NMOS transistor, and drives the fourth test pattern TPT4 to the ground voltage VSS by the NMOS transistor. The NN driver drives the fourth test pattern TPT4 to the ground voltage VSS, and then drives the fourth test pattern TPT4 to the (power supply voltage VDD-threshold voltage Vₜₕ).

The first strobe line 315-1 is electrically connected between the first test driver 313-1 and the strobe signal synthesis circuit 317. The first test pattern TPT1 output from the first test driver 313-1 is transmitted through the first strobe line 315-1 and is received by the strobe signal synthesis circuit 317 as a first test strobe signal TSTB1. The first test strobe signal TSTB1 is generated by transmitting the first test pattern TPT1 driven by the first test driver 313-1 implemented as the PN driver through the first strobe line 315-1. Therefore, the point in time when the logic level of the first test strobe signal TSTB1 transitions from a logic low level to a logic high level may be determined by a driving force of the first test driver 313-1 and transmission characteristics of the first strobe line 315-1.

The second strobe line 315-2 is electrically connected between the second test driver 313-2 and the strobe signal synthesis circuit 317. The second test pattern TPT2 output from the second test driver 313-2 is transmitted through the second strobe line 315-2 and received by the strobe signal synthesis circuit 317 as a second test strobe signal TSTB2. The second test strobe signal TSTB2 is generated by transmitting the second test pattern TPT2 driven by the second test driver 313-2 implemented as the NN driver through the second strobe line 315-2. Therefore, the point in time when the logic level of the second test strobe signal TSTB2 transitions from a logic low level to a logic high level may be determined by the driving force of the second test driver 313-2 and the transmission characteristics of the second strobe line 315-2.

The third strobe line 315-3 is electrically connected between the third test driver 313-3 and the strobe signal synthesis circuit 317. The third test pattern TPT3 output from the third test driver 313-3 is transmitted through the third strobe line 315-3 and received by the strobe signal synthesis circuit 317 as a third test strobe signal TSTB3. The third test strobe signal TSTB3 is generated by transmitting the third test pattern TPT3 driven by the third test driver 313-3 implemented as the PN driver through the third strobe line 315-3. Therefore, the point in time when the logic level of the third test strobe signal TSTB3 transitions from a logic low level to a logic high level may be determined by the driving force of the third test driver 313-3 and the transmission characteristics of the third strobe line 315-3.

The fourth strobe line 315-4 is electrically connected between the fourth test driver 313-4 and the strobe signal synthesis circuit 317. The fourth test pattern TPT4 output from the fourth test driver 313-4 is transmitted through the fourth strobe line 315-4 and received by the strobe signal synthesis circuit 317 as a fourth test strobe signal TSTB4. The fourth test strobe signal TSTB4 is generated by transmitting the fourth test pattern TPT4 driven by the fourth test driver 313-4 implemented as the NN driver through the fourth strobe line 315-4. Therefore, the point in time when the logic level of the fourth test strobe signal TSTB4 transitions from a logic low level to a logic high level may be determined by the driving force of the fourth test driver 313-4 and the transmission characteristics of the fourth strobe line 315-4.

The strobe signal synthesis circuit 317 is electrically connected to the first strobe line 315-1, the second strobe line 315-2, the third strobe line 315-3, and the fourth strobe line 315-4, receives the first test strobe signal TSTB1 from the first strobe line 315-1, receives the second test strobe signal TSTB2 from the second strobe line 315-2, receives the third test strobe signal TSTB3 from the third strobe line 315-3, and receives the fourth test strobe signal TSTB4 from the fourth strobe line 315-4. The strobe signal synthesis circuit 317 generates the synthetic test strobe signal TSTB-S based on the first test strobe signal TSTB1, the second test strobe signal TSTB2, the third test strobe signal TSTB3, and the fourth test strobe signal TSTB4. The strobe signal synthesis circuit 317 generates the synthetic test strobe signal TSTB-S having a logic level that transitions in synchronization with a latest logic level transition time among the logic level transition times of the first test strobe signal TSTB1, the second test strobe signal TSTB2, the third test strobe signal TSTB3, and the fourth test strobe signal TSTB4. For example, when the logic level of the first test strobe signal TSTB1 transitions from a logic low level to a logic high level at a first point in time, the logic level of the second test strobe signal TSTB2 transitions from a logic low level to a logic high level at a second point in time, the logic level of the third test strobe signal TSTB3 transitions from a logic high level to a logic low level at a third point in time, and the logic level of the fourth test strobe signal TSTB4 transitions from a logic high level to a logic low level at a fourth point in time, and the third point in time is the latest among the first to fourth points in time, the strobe signal synthesis circuit 317 generates the synthetic test strobe signal TSTB-S having a logic level that transitions from a logic low level to a logic high level in synchronization with the third point in time.

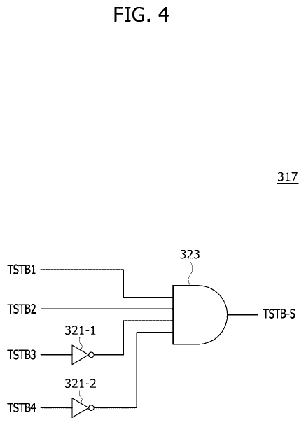

FIG. 4 illustrates a strobe signal synthesis circuit 317 according to an embodiment of the present disclosure, for example, as shown in FIG. 3.

As shown in FIG. 4, the strobe signal synthesis circuit 317 includes inverters 321-1 and 321-2 and an AND gate 323. The inverter 321-1 inversely buffers a third test strobe signal TSTB3 and outputs an inversely buffered signal of the third test strobe signal TSTB3, and the inverter 321-2 inversely buffers a fourth test strobe signal TSTB4 and outputs an inversely buffered signal of the fourth test strobe signal TSTB4. The AND gate 323 receives a first test strobe signal TSTB1, a second test strobe signal TSTB2, an output signal of the inverter 321-1, and an output signal of the inverter 321-2 and performs a logical AND operation. The strobe signal synthesis circuit 317 generates a synthetic test strobe signal TSTB-S having a logic level that transitions from a logic low level to a logic high level in synchronization with a latest logic level transition time among the logic level transition times of the first test strobe signal TSTB1, the second test strobe signal TSTB2, the third test strobe signal TSTB3, and the fourth test strobe signal TSTB4.

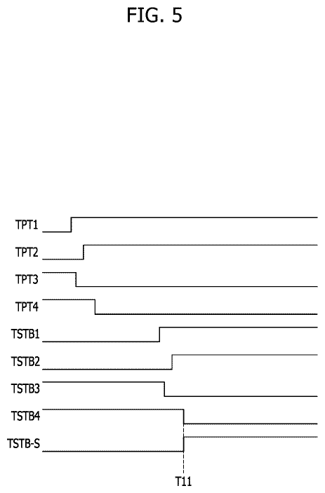

FIG. 5 is a timing diagram during an operation of a strobe signal synthesis circuit 317 according to an embodiment of the present disclosure, for example, as shown in FIG. 3 and FIG. 4.

As shown in FIG. 5, the logic level of a first test pattern TPT1 driven by a first test driver 313-1 in FIG. 3 implemented as a PN driver, the logic level of a second test pattern TPT2 driven by a second test driver 313-2 implemented as an NN driver, the logic level of a third test pattern TPT3 driven by a third test driver 313-3 implemented as a PN driver, and the logic level of a fourth test pattern TPT4 driven by a fourth test driver 313-4 implemented as an NN driver transition at different points in time. The logic level of a first test strobe signal TSTB1 generated by transmitting the first test pattern TPT1 through a first strobe line 315-1, the logic level of a second test strobe signal TSTB2 generated by transmitting the second test pattern TPT2 through a second strobe line 315-2, the logic level of a third test strobe signal TSTB3 generated by transmitting the third test pattern TPT3 through a third strobe line 315-3, and the logic level of a fourth test strobe signal TSTB4 generated by transmitting the fourth test pattern TPT4 through a fourth strobe line 315-4 transition at different points in time. The synthetic test strobe signal TSTB-S is generated in synchronization with a latest logic level transition time T11 among logic level transition times of the first test strobe signal TSTB1, the second test strobe signal TSTB2, the third test strobe signal TSTB3, and the fourth test strobe signal TSTB4, that is, the point in time when the logic level of the fourth test strobe signal TSTB4 transitions from a logic high level to a logic low level.

FIG. 6 illustrates a strobe signal comparison circuit 305 according to an embodiment of the present disclosure, for example, as shown in FIG. 2.

As shown in FIG. 6, the strobe signal comparison circuit 305 includes a first strobe signal delay circuit 331-1, a first calibration code latch circuit 333-1, a second strobe signal delay circuit 331-2, a second calibration code latch circuit 333-2, a third strobe signal delay circuit 331-3, and a third calibration code latch circuit 333-3.

The first strobe signal delay circuit 331-1 delays a clock strobe signal CLK-STB by a first unit delay period based on a power supply voltage VDD to generate a first delayed strobe signal STB1D. The first strobe signal delay circuit 331-1 may be implemented as an RC delay circuit, but this is only an example and the present disclosure is not limited thereto. The capacitor included in the first strobe signal delay circuit 331-1 may be implemented as a MOS transistor that receives a ground voltage VSS through a gate.

The first calibration code latch circuit 333-1 is electrically connected to the first strobe signal delay circuit 331-1 and receives the first delayed strobe signal STB1D from the first strobe signal delay circuit 331-1. The first calibration code latch circuit 333-1 generates a first bit CAL-CD<0> of a calibration code based on the first delayed strobe signal STB1D and a synthetic test strobe signal TSTB-S. The first calibration code latch circuit 333-1 latches the synthetic test strobe signal TSTB-S in synchronization with a rising edge of the first delayed strobe signal STB1D and outputs the latched synthetic test strobe signal TSTB-S as the first bit CAL-CD<0> of the calibration code.

The second strobe signal delay circuit 331-2 delays the first delayed strobe signal STB1D by a second unit delay period based on the power supply voltage VDD to generate a second delayed strobe signal STB2D. The second strobe signal delay circuit 331-2 may be implemented as an RC delay circuit, but this is only an example and the present disclosure is not limited thereto. The second unit delay period may be set identically to the first unit delay period, but this is only an example and the present disclosure is not limited thereto.

The second calibration code latch circuit 333-2 is electrically connected to the second strobe signal delay circuit 331-2 and receives the second delayed strobe signal STB2D from the second strobe signal delay circuit 331-2. The second calibration code latch circuit 333-2 generates a second bit CAL-CD<1> of the calibration code based on the second delayed strobe signal STB2D and the synthetic test strobe signal TSTB-S. The second calibration code latch circuit 333-2 latches the synthetic test strobe signal TSTB-S in synchronization with a rising edge of the second delayed strobe signal STB2D and outputs the latched synthetic test strobe signal TSTB-S as the second bit CAL-CD<1> of the calibration code.

The third strobe signal delay circuit 331-3 delays the second delayed strobe signal STB2D by a third unit delay period based on the power supply voltage VDD to generate a third delayed strobe signal STB3D. The third strobe signal delay circuit 331-3 may be implemented as an RC delay circuit, but this is only an example and the present disclosure is not limited thereto. The third unit delay period may be set identically to the first unit delay period and the second unit delay period, but this is only an example and the present disclosure is not limited thereto.

The third calibration code latch circuit 333-3 is electrically connected to the third strobe signal delay circuit 331-3 and receives the third delayed strobe signal STB3D from the third strobe signal delay circuit 331-3. The third calibration code latch circuit 333-3 generates a third bit CAL-CD<2> of the calibration code based on the third delayed strobe signal STB3D and the synthetic test strobe signal TSTB-S. The third calibration code latch circuit 333-3 latches the synthetic test strobe signal TSTB-S in synchronization with a rising edge of the third delayed strobe signal STB3D and outputs the latched synthetic test strobe signal TSTB-S as the third bit CAL-CD<2> of the calibration code.

The strobe signal comparison circuit 305 latches the synthetic test strobe signal TSTB-S in synchronization with the first delayed strobe signal STB1D generated by delaying the clock strobe signal CLK-STB by the first unit delay period, and inverts the latched synthetic test strobe signal TSTB-S to output the first bit CAL-CD<0> of the calibration code. The strobe signal comparison circuit 305 latches the synthetic test strobe signal TSTB-S in synchronization with the second delayed strobe signal STB2D generated by delaying the first delayed strobe signal STB1D by the second unit delay period, and inverts the latched synthetic test strobe signal TSTB-S to output the second bit CAL-CD<1> of the calibration code. The strobe signal comparison circuit 305 latches the synthetic test strobe signal TSTB-S in synchronization with the third delayed strobe signal STB3D generated by delaying the second delayed strobe signal STB2D by the third unit delay period, and inverts the latched synthetic test strobe signal TSTB-S to output the third bit CAL-CD<2> of the calibration code. FIG. 6 illustrates only the first to third strobe signal delay circuits 331-1, 331-2, and 331-3 and the first to third calibration code latch circuits 333-1, 333-2, and 333-3 that generate the first to third bits CAL-CD<0:2> of the calibration code, respectively, but the number of strobe signal delay circuits and the number of calibration code latch circuits may be increased proportionally depending on the number of calibration codes.

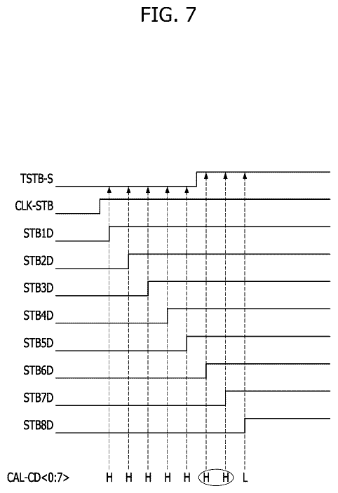

FIG. 7 is a timing diagram during an operation of a strobe signal comparison circuit 305 according to an embodiment of the present disclosure, for example, as shown in FIG. 6.

As shown in FIG. 7, the strobe signal comparison circuit 305 latches a synthetic test strobe signal TSTB-S in synchronization with a first delayed strobe signal STB1D generated by delaying a clock strobe signal CLK-STB by a first unit delay period, and inverts the latched synthetic test strobe signal TSTB-S to generate a first bit CAL-CD<0> of the calibration code of a logic high level H.

As shown in FIG. 7, the strobe signal comparison circuit 305 latches the synthetic test strobe signal TSTB-S in synchronization with a second delayed strobe signal STB2D generated by delaying the first delayed strobe signal STB1D by a second unit delay period, and inverts the latched synthetic test strobe signal TSTB-S to generate a second bit CAL-CD<1> of the calibration code of a logic high level H.

As shown in FIG. 7, the strobe signal comparison circuit 305 latches the synthetic test strobe signal TSTB-S in synchronization with a third delayed strobe signal STB3D generated by delaying the second delayed strobe signal STB2D by a third unit delay period, and inverts the latched synthetic test strobe signal TSTB-S to generate a third bit CAL-CD<2> of the calibration code of a logic high level H.

As shown in FIG. 7, the strobe signal comparison circuit 305 latches the synthetic test strobe signal TSTB-S in synchronization with a fourth delayed strobe signal STB4D generated by delaying the third delayed strobe signal STB3D by a fourth unit delay period, and inverts the latched synthetic test strobe signal TSTB-S to generate a fourth bit CAL-CD<3> of the calibration code of the logic high level H.

As shown in FIG. 7, the strobe signal comparison circuit 305 latches the synthetic test strobe signal TSTB-S in synchronization with a fifth delayed strobe signal STB5D generated by delaying the fourth delayed strobe signal STB4D by a fifth unit delay period, and inverts the latched synthetic test strobe signal TSTB-S to generate a fifth bit CAL-CD<4> of the calibration code of the logic high level H.

As shown in FIG. 7, the strobe signal comparison circuit 305 latches the synthetic test strobe signal TSTB-S in synchronization with a sixth delayed strobe signal STB6D generated by delaying the fifth delayed strobe signal STB5D by a sixth unit delay period, and outputs the latched synthetic test strobe signal TSTB-S as a sixth bit CAL-CD<5> of the calibration code of the logic high level H.

As shown in FIG. 7, the strobe signal comparison circuit 305 latches the synthetic test strobe signal TSTB-S in synchronization with a seventh delayed strobe signal STB7D generated by delaying the sixth delayed strobe signal STB6D by a seventh unit delay period, and outputs the latched synthetic test strobe signal TSTB-S as a seventh bit CAL-CD<6> of the calibration code of the logic high level H.

The sixth and seventh bits CAL-CD<5:6> of the calibration code are not generated by inverting the latched synthetic test strobe signal TSTB-S unlike the first to fifth bits CAL-CD<0:4> of the calibration code. This is to increase the period in which the sixth and seventh bits CAL-CD<5:6> of the calibration code are generated at a logic high level by the sixth and seventh unit delay periods from a point in time when a logic level of the synthetic test strobe signal TSTB-S transitions from a logic low level to a logic high level, thereby, in an embodiment, enabling signals such as data, command, and address to be transmitted using a stable strobe signal by using the synthetic test strobe signal TSTB-S.

As shown in FIG. 7, the strobe signal comparison circuit 305 latches the synthetic test strobe signal TSTB-S in synchronization with an eighth delayed strobe signal STB8D generated by delaying the seventh delayed strobe signal STB7D by an eighth delay period, and inverts the latched synthetic test strobe signal TSTB-S to generate an eighth bit CAL-CD<7> of the calibration code of a logic low level L.

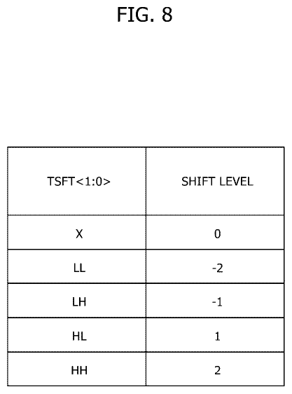

FIG. 8 to FIG. 10 are tables during an operation of a code shifting circuit 131, included a write code shifting circuit 131-1 and a read code shifting circuit 131-2, according to an example of the present disclosure, for example, as shown in FIG. 1.

As shown in FIG. 8, the shifting test mode signal TSFT received by a code shifting circuit 131 is set to have a binary bit set depending on shifting levels. As shown in a first row of FIG. 8, when the shifting test mode signal TSFT is not received, the shifting level is set to 0. When the shifting test mode signal TSFT is not received, it means that the binary bit set of the shifting test mode signal TSFT is not set to one of “LL”, “LH”, “HL”, and “HH”. As shown in a second row of FIG. 8, when the shifting level is −2, the shifting test mode signal TSFT is set to have a binary bit set of “LL”. As shown in a third row of FIG. 8, when the shifting level is −1, the shifting test mode signal TSFT is set to have a binary bit set of “LH”. As shown in a fourth row of FIG. 8, when the shifting level is 1, the shifting test mode signal TSFT is set to have a binary bit set of “HL”. As shown in a fifth row of FIG. 8, when the shifting level is 2, the shifting test mode signal TSFT is set to have a binary bit set of “HH”.

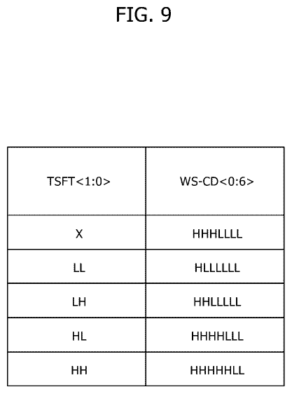

As shown in FIG. 9, the write code shifting circuit 131-1 included in the code shifting circuit 131 shifts the calibration code CAL-CD<0:6> by the shifting level according to the shifting test mode signal TSFT<1:0> to generate the write shifting code WS-CD<0:6>.

As shown in a first row of FIG. 9, when the shifting test mode signal TSFT<1:0> is not received and the shifting level is set to 0, the write code shifting circuit 131-1 does not shift the calibration code CAL-CD<0:6> having a binary bit set of “HHHLLLL”, but outputs the calibration code CAL-CD<0:6> as the write shifting code WS-CD<0:6>.

As shown in a second row of FIG. 9, when the shifting level is set to −2 and the shifting test mode signal TSFT<1:0> having a binary bit set of “LL” is received, the write code shifting circuit 131-1 shifts the calibration code CAL-CD<0:6> having a binary bit set of “HHHLLLL” so that the number of bits set to “H” is decreased by 2 bits and generates the write shifting code WS-CD<0:6> having a binary bit set of “HLLLLLL”.

As shown in a third row of FIG. 9, when the shifting level is set to −1 and the shifting test mode signal TSFT<1:0> having a binary bit set of “LH” is received, the write code shifting circuit 131-1 shifts the calibration code CAL-CD<0:6> having a binary bit set of “HHHLLLL” so that the number of bits set to “H” is decreased by 1 and generates the write shifting code WS-CD<0:6> having a binary bit set of “HHLLLLL”.

As shown in a fourth row of FIG. 9, when the shifting level is set to 1 and the shifting test mode signal TSFT<1:0> having a binary bit set of “HL” is received, the write code shifting circuit 131-1 shifts the calibration code CAL-CD<0:6> having a binary bit set of “HHHLLLL” so that the number of bits set to “H” is increased by 1 and generates the write shifting code WS-CD<0:6> having a binary bit set of “HHHHLLL”.

As shown in a fifth row of FIG. 9, when the shifting level is set to 2 and the shifting test mode signal TSFT<1:0> having a binary bit set of “HH” is received, the write code shifting circuit 131-1 shifts the calibration code CAL-CD<0:6> having a binary bit set of “HHHLLLL” so that the number of bits set to “H” is increased by 2 and generates the write shifting code WS-CD<0:6> having a binary bit set of “HHHHHLL”.

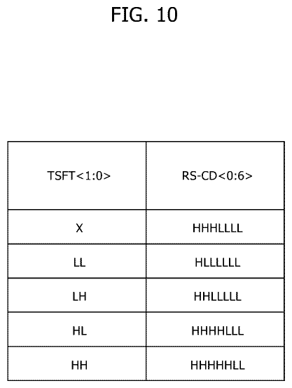

As shown in FIG. 10, the read code shifting circuit 131-2 included in the code shifting circuit 131 shifts the calibration code CAL-CD<0:6> by a shifting level according to the shifting test mode signal TSFT<1:0> to generate a read shifting code RS-CD<0:6>.

As shown in a first row of FIG. 10, when the shifting test mode signal TSFT<1:0> is not received and the shifting level is set to 0, the read code shifting circuit 131-2 does not shift the calibration code CAL-CD<0:6> having a binary bit set of “HHHLLLL”, but outputs the calibration code CAL-CD<0:6> as the read shifting code RS-CD<0:6>.

As shown in a second row of FIG. 10, when the shifting level is set to −2 and the shifting test mode signal TSFT<1:0> having a binary bit set of “LL” is received, the read code shifting circuit 131-2 shifts the calibration code CAL-CD<0:6> having the binary bit set of “HHHLLLL” so that the number of bits set to “H” is decreased by 2 and generates the read shifting code RS-CD<0:6> having a binary bit set of “HLLLLLL”.

As shown in a third row of FIG. 10, when the shifting level is set to −1 and the shifting test mode signal TSFT<1:0> having a binary bit set of “LH” is received, the read code shifting circuit 131-2 shifts the calibration code CAL-CD<0:6> having the binary bit set of “HHHLLLL” so that the number of bits set to “H” is decreased by 1 and generates the read shifting code RS-CD<0:6> having a binary bit set of “HHLLLLL”.

As shown in a fourth row of FIG. 10, when the shifting level is set to 1 and the shifting test mode signal TSFT<1:0> having a binary bit set of “HL” is received, the read code shifting circuit 131-2 shifts the calibration code CAL-CD<0:6> having a binary bit set of “HHHLLLL” so that the number of bits set to “H” is increased by 1 and generates the read shifting code RS-CD<0:6> having a binary bit set of “HHHHLLL”.

As shown in a fifth row of FIG. 10, when the shifting level is set to 2 and the shifting test mode signal TSFT<1:0> having a binary bit set of “HH” is received, the read code shifting circuit 131-2 shifts the calibration code CAL-CD<0:6> having a binary bit set of “HHHLLLL” so that the number of bits set to “H” is increased by 2 and generates the read shifting code RS-CD<0:6> having a binary bit set of “HHHHHLL”.

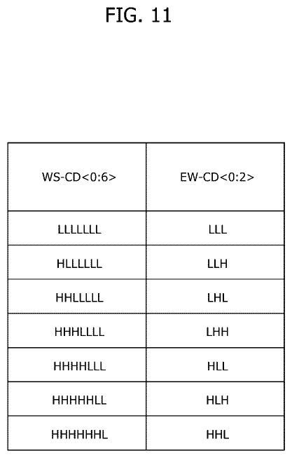

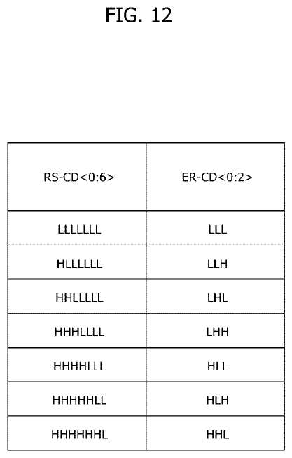

FIG. 11 and FIG. 12 are tables during an operation of a code encoder 133, according to an example of the present disclosure, for example, as shown in FIG. 1.

As shown in FIG. 11, a write code encoder 133-1 included in the code encoder 133 encodes a write shifting code WS-CD<0:6> to generate an encoding write code EW-CD<0:2>.

As shown in a first row of FIG. 11, the write code encoder 133-1 encodes the write shifting code WS-CD<0:6> having a binary bit set of “LLLLLLLL” to generate the encoding write code EW-CD<0:2> having a binary bit set of “LLL”.

As shown in a second row of FIG. 11, the write code encoder 133-1 encodes the write shifting code WS-CD<0:6> having a binary bit set of “HLLLLLLL” to generate the encoding write code EW-CD<0:2> having a binary bit set of “LLH”.

As Shown in a third row of FIG. 11, the write code encoder 133-1 encodes the write shifting code WS-CD<0:6> having a binary bit set of “HHLLLLLL” to generate the encoding write code EW-CD<0:2> having a binary bit set of “LHL”.

As shown in a fourth row of FIG. 11, the write code encoder 133-1 encodes the write shifting code WS-CD<0:6> having a binary bit set of “HHHLLLLL” to generate the encoding write code EW-CD<0:2> having a binary bit set of “LHH”.

As shown in a fifth row of FIG. 11, the write code encoder 133-1 encodes the write shifting code WS-CD<0:6> having a binary bit set of “HHHHLLL” to generate the encoding write code EW-CD<0:2> having a binary bit set of “HLL”.

As shown in a sixth row of FIG. 11, the write code encoder 133-1 encodes the write shifting code WS-CD<0:6> having a binary bit set of “HHHHHLL” to generate the encoding write code EW-CD<0:2> having a binary bit set of “HLH”.

As shown in a seventh row of FIG. 11, the write code encoder 133-1 encodes the write shifting code WS-CD<0:6> having a binary bit set of “HHHHHHL” to generate the encoding write code EW-CD<0:2> having a binary bit set of “HHL”.

As shown in FIG. 12, the read code encoder 133-2 included in the code encoder 133 encodes a read shifting code RS-CD<0:6> to generate an encoding read code ER-CD<0:2>.

As shown in a first row of FIG. 12, the read encoder 133-2 encodes the read shifting code RS-CD<0:6> having a binary bit set of “LLLLLLL” to generate the encoding read code ER-CD<0:2> having a binary bit set of “LLL”.

As shown in a second row of FIG. 12, the read encoder 133-2 encodes the read shifting code RS-CD<0:6> having a binary bit set of “HLLLLLL” to generate the encoding read code ER-CD<0:2> having a binary bit set of “LLH”.

As shown in a third row of FIG. 12, the read encoder 133-2 encodes the read shifting code RS-CD<0:6> having a binary bit set of “HHLLLLL” to generate the encoding read code ER-CD<0:2> having a binary bit set of “LHL”.

As shown in a fourth row of FIG. 12, the read encoder 133-2 encodes the read shifting code RS-CD<0:6> having a binary bit set of “HHHLLLL” to generate the encoding read code ER-CD<0:2> having a binary bit set of “LHH”.

As shown in a fifth row of FIG. 12, the read encoder 133-2 encodes the read shifting code RS-CD<0:6> having a binary bit set of “HHHHLLL” to generate the encoding read code ER-CD<0:2> having a binary bit set of “HLL”.

As shown in a sixth row of FIG. 12, the read encoder 133-2 encodes the read shifting code RS-CD<0:6> having a binary bit set of “HHHHHLL” to generate the encoding read code ER-CD<0:2> having a binary bit set of “HLH”.

As shown in a seventh row of FIG. 12, the read encoder 133-2 encodes the read shifting code RS-CD<0:6> having a binary bit set of “HHHHHHL” to generate the encoding read code ER-CD<0:2> having a binary bit set of “HHL”.

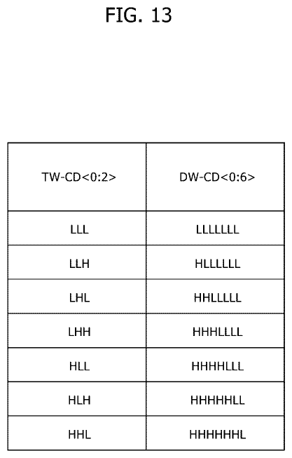

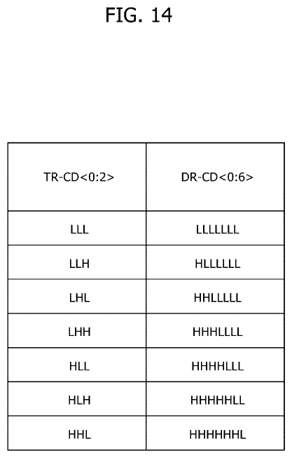

FIG. 13 and FIG. 14 are tables during an operation of a code decoder 21, included a write code decoder 21-1 and a read code decoder 21-2, according to an example of the present disclosure, for example, as shown in FIG. 1.

As shown in FIG. 13, a write code decoder 21-1 included in the code decoder 21 decodes a transmission write code TW-CD<0:2> to generate a decoded write code DW-CD<0:6>.

As shown in a first row of FIG. 13, the write code decoder 21-1 decodes the transmission write code TW-CD<0:2> having a binary bit set of “LLL” to generate the decoded write code DW-CD<0:6> having a binary bit set of “LLLLLLL”.

As shown in a second row of FIG. 13, the write code decoder 21-1 decodes the transmission write code TW-CD<0:2> having a binary bit set of “LLH” to generate the decoded write code DW-CD<0:6> having a binary bit set of “HLLLLLL”.

As shown in a third row of FIG. 13, the write code decoder 21-1 decodes the transmission write code TW-CD<0:2> having a binary bit set of “LHL” to generate the decoded write code DW-CD<0:6> having a binary bit set of “HHLLLLL”.

As shown in a fourth row of FIG. 13, the write code decoder 21-1 decodes the transmission write code TW-CD<0:2> having a binary bit set of “LHH” to generate the decoded write code DW-CD<0:6> having a binary bit set of “HHHLLLL”.

As shown in a fifth row of FIG. 13, the write code decoder 21-1 decodes the transmission write code TW-CD<0:2> having a binary bit set of “HLL” to generate the decoded write code DW-CD<0:6> having a binary bit set of “HHHHLLL”.

As shown in a sixth row of FIG. 13, the write code decoder 21-1 decodes the transmission write code TW-CD<0:2> having a binary bit set of “HLH” to generate the decoded write code DW-CD<0:6> having a binary bit set of “HHHHHLL”.

As shown in a seventh row of FIG. 13, the write code decoder 21-1 decodes the transmission write code TW-CD<0:2> having a binary bit set of “HHL” to generate the decoded write code DW-CD<0:6> having a binary bit set of “HHHHHHL”.

As shown in FIG. 14, a read code decoder 21-2 included in the code decoder 21 decodes a transmission read code TR-CD<0:2> to generate a decoded read code DR-CD<0:6>.

As shown in a first row of FIG. 14, the read code decoder 21-2 decodes the transmission read code TR-CD<0:2> having a binary bit set of “LLL” to generate the decoded read code DR-CD<0:6> having a binary bit set of “LLLLLLL”.

As shown in a second row of FIG. 14, the read code decoder 21-2 decodes the transmission read code TR-CD<0:2> having a binary bit set of “LLH” to generate the decoded read code DR-CD<0:6> having a binary bit set of “HLLLLLL”.

As shown in a third row of FIG. 14, the read code decoder 21-2 decodes the transmission read code TR-CD<0:2> having a binary bit set of “LHL” to generate the decoded read code DR-CD<0:6> having a binary bit set of “HHLLLLL”.

As shown in a fourth row of FIG. 14, the read code decoder 21-2 decodes the transmission read code TR-CD<0:2> having a binary bit set of “LHH” to generate the decoded read code DR-CD<0:6> having a binary bit set of “HHHLLLL”.

As shown in a fifth row of FIG. 14, the read code decoder 21-2 decodes the transmission read code TR-CD<0:2> having a binary bit set of “HLL” to generate the decoded read code DR-CD<0:6> having a binary bit set of “HHHHLLL”.

As shown in a sixth row of FIG. 14, the read code decoder 21-2 decodes the transmission read code TR-CD<0:2> having a binary bit set of “HLH” to generate the decoded read code DR-CD<0:6> having a binary bit set of “HHHHHLL”.

As shown in a seventh row of FIG. 14, the read code decoder 21-2 decodes the transmission read code TR-CD<0:2> having a binary bit set of “HHL” to generate the decoded read code DR-CD<0:6> having a binary bit set of “HHHHHHL”.

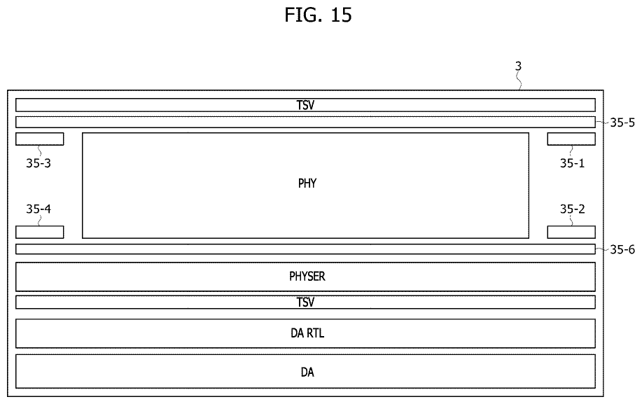

FIG. 15 illustrates a base die 3 according to an embodiment of the present disclosure.

As shown in FIG. 15, the base die 3 includes a physical layer (PHY), a serial-to-parallel conversion circuit (PHYSER), alignment circuits 35-1, 35-2, 35-3, 35-4, 35-5, and 35-6, through via regions (TSV), a direct access region (DA), and a logic circuit region (DA RTL).

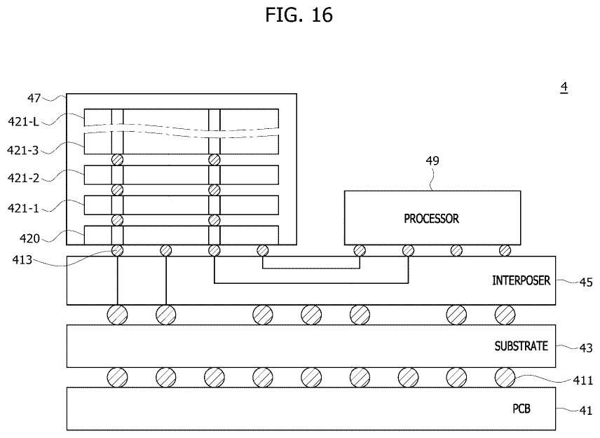

The physical layer (PHY) controls transmission of data, commands, and addresses between core dies and a processor, for example, a processor 49 in FIG. 16, through a plurality of channels. The physical layer (PHY) includes data control circuits that control the transmission of data through the plurality of channels and command address control circuits that control the transmission of commands and addresses through the plurality of channels. The physical layer (PHY) is used for high-speed data transmission, maintaining signal integrity, and low-power design in high bandwidth memory (HBM) systems.

The serial-to-parallel conversion circuit (PHYSER) converts serial signals transmitted serially through the physical layer (PHY) into parallel signals, aligns the converted parallel signals through the alignment circuits 35-1, 35-2, 35-3, 35-4, 35-5, and 35-6, and then transmits the converted and aligned parallel signals to the through via regions (TSV). According to an embodiment, the first alignment circuit 1 of FIG. 1 may be disposed in some of the alignment circuits 35-1, 35-2, 35-3, and 35-4, and the second alignment circuit 2 of FIG. 1 may be disposed in the remaining alignment circuits 35-5, and 35-6. However, this is only an example and the present disclosure is not limited thereto. Positions and numbers of the alignment circuits 35-1, 35-2, 35-3, 35-4, 35-5, and 35-6 may be variously modified according to an embodiment.

The through via region (TSV) includes a plurality of through vias that connect the base die 3 and a plurality of core dies, and transmits the parallel signals transmitted from the serial-to-parallel conversion circuit (PHYSER) to the core dies or output the parallel signals transmitted from the core dies to the serial-to-parallel conversion circuit (PHYSER).

The direct access region (DA) includes pads used to directly access the core dies without going through a memory controller, etc. from a processor, for example, the processor 49 in FIG. 16. Signals used for performing various tests, such as tests based on the IEEE 1500 standard, may be transmitted through the direct access region (DA). In an embodiment, the direct access region (DA) can provide low latency and high bandwidth, and can reduce power consumption.

The logic circuit region (DA RTL) is implemented as a register transfer level (RTL) circuit and can control or test the operation of core dies, for example, core dies 421-1 to 421-L in FIG. 16, stacked over the base die 3.

FIG. 16 illustrates a memory system 4 according to an embodiment of the present disclosure.

As shown in FIG. 16, the memory system 4 includes a printed circuit board (PCB) 41, a substrate 43, an interposer 45, a memory device 47, and a processor 49.

The printed circuit board 41 connects various electronic components to each other to form electronic circuits. The electronic circuits include the memory system 4. A copper (Cu) layer, a solder mask, a silk screen, and so forth are formed on the printed circuit board 41. Circuit paths that transmit or transfer signals or power are formed in the copper (Cu) layer. In an embodiment, the solder mask prevents or mitigates damage to the circuits and protects a specific region where components are soldered. The silk screen indicates location or information for the electronic components as characters or symbols printed on a surface of the printed circuit board 41.

The substrate 43 is disposed over the printed circuit board 41 with bump pads in between, for example, bump pads 411 and mechanically supports the interposer 45, the memory device 47, and the processor 49. The substrate 43 functions as a physical base for the printed circuit board 41 and is an insulator. The substrate 43 may include materials such as flame retardant material grade/type 4 (FR4) that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 45 is disposed over the substrate 43 with bump pads in between and includes wiring that connects electronic components, for example, the memory device 47 and the processor 49, that have form factors or pin arrangements do not match or have different spacing. The interposer 45 converts signals from different interfaces, such as double data rate (DDR), high bandwidth memory (HBM), and peripheral component interconnect express (PCIe).

The memory device 47 is disposed over the interposer 45 with pads, for example, micro bump pads 413, in between. The memory device 47 stores data received from the processor 49 or outputs the stored data to the processor 49 under control of the processor 49. The memory device 47 includes a base die 420 and a plurality of core dies 421-1 to 421-L, where L is an integer greater than 1. The core dies 421-1 to 421-L are stacked over the base die 420 with micro bump pads in between. The base die 420 and the core dies 421-1 to 421-L are vertically connected to each other using through vias and micro bump pads. The base die 420 controls efficient data transmission between the processor 49 and the core dies 421-1 to 421-L. The base die 420 receives input/output power voltage (voltage drain drain for IO also referred to as output stage drain power voltage) VDDQ as an operating voltage utilized during operation of internal circuits included in the base die 420. The base die 420 receives the input/output power voltage VDDQ from the printed circuit board 41 through the substrate 43 and the interposer 45. The input/output power voltage VDDQ is a voltage supplied to buffers that transmit data and is distinguished or different from the power supply voltage VDD. The core dies 421-1 to 421-L use a peripheral voltage VPERI as an operating voltage during operation of the internal circuits included in the core dies 421-1 to 421-L. The core dies 421-1 to 421-L generate the peripheral voltage VPERI from the input/output power voltage VDDQ received through the base die 420. The core dies 421-1 to 421-L generate the peripheral voltage VPERI at a lower voltage level than the input/output power voltage VDDQ and use the peripheral voltage VPERI as an operating voltage. Each of the core dies 421-1 to 421-L includes a plurality of channel regions, for example, eight channel regions or forty-six channel regions, that operate independently. Each of the plurality of channel regions is allocated with a channel operating independently to receive or transmit data. The number L of core dies 421-1 to 421-L may be four, eight, thirty-two, forty-six, and so forth. For example, when each of the core dies 421-1 to 421-12 has eight channels, the core dies 421-1 to 421-4, the core dies 421-5 to 421-8, and the core dies 421-9 to 421-12 each include thirty-two channel regions, and transmit and receive data with the processor 49 in units of a rank including thirty-two channels.

The base die 420 may be implemented as the base die 3 shown in FIG. 15, and the base die 420 may include the first alignment circuit 1 and the second alignment circuit 2 shown in FIG. 1. In an embodiment, the first alignment circuit 1 divides and encodes a calibration code generated to calibrate the clock signal for each write operation and read operation to generate and transmit a transmission write code and a transmission read code, thereby reducing the number of transmission lines and reducing the layout area and power consumption. In addition, the first alignment circuit 1 divides and encodes the calibration code generated to calibrate the clock signal for each write operation and read operation to generate and transmit the transmission write code and the transmission read code, and the second alignment circuit 2 decodes the transmission write code and the transmission read code in the data alignment circuit and uses the transmission write code and the transmission read code to calibrate write strobe signal and read strobe signal, thereby, in an embodiment, reducing the layout area and power consumption of the data alignment circuit.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A memory device comprising:
a calibration code generation circuit configured to generate a calibration code based on a calibration test mode signal and a calibrated clock signal;
a transmission code generation circuit configured to shift the calibration code based on a shifting test mode signal to generate a shifting code, encode the shifting code to generate an encoding code, and generate and transmit a transmission code based on the encoding code; and
a clock calibration circuit configured to calibrate a clock signal according to a selected calibration code generated based on the calibration code to generate the calibrated clock signal.

2. The memory device of claim 1, wherein the transmission code generation circuit comprises:
a code shifting circuit configured to generate the shifting code; and
a code encoder configured to generate the encoding code.

3. The memory device of claim 2, wherein the code shifting circuit comprises:
a write code shifting circuit configured to shift the calibration code based on the shifting test mode signal to generate a write shifting code; and
a read code shifting circuit configured to shift the calibration code based on the shifting test mode signal to generate a read shifting code.

4. The memory device of claim 3, wherein the code encoder comprises:
a write code encoder configured to encode the write shifting code to generate an encoding write code; and
a read code encoder configured to encode the read shifting code to generate an encoding read code.

5. The memory device of claim 4,
wherein the write code encoder generates the encoding write code including fewer bits than bits included in the write shifting code, and
wherein the read code encoder generates the encoding read code including fewer bits than bits included in the read shifting code.

6. The memory device of claim 4, wherein the transmission code generation circuit further comprises:
a write transmission code selection circuit configured to select and output one of the encoding write code and a manual write code based on a manual activation signal as a transmission write code; and
a read transmission code selection circuit configured to select and output one of the encoding read code and a manual read code based on the manual activation signal as a transmission read code.

7. The memory device of claim 1, further comprising:
a code decoder configured to decode the transmission code to generate a decoded code; and
a strobe signal calibration circuit configured to calibrate a strobe signal based on the decoded code to generate a calibrated strobe signal.

8. The memory device of claim 7, wherein the code decoder generates the decoded code set to include the same number of bits as the calibration code.

9. The memory device of claim 7,
wherein the code decoder comprises:
a write code decoder configured to decode a transmission write code to generate a decoded write code; and
a read code decoder configured to decode a transmission read code to generate a decoded read code, and
wherein the strobe signal calibration circuit comprises:
a write strobe signal calibration circuit configured to calibrate a write strobe signal based on the decoded write code to generate a calibrated write strobe signal; and
a read strobe signal calibration circuit configured to calibrate a read strobe signal based on the decoded read code to generate a calibrated read strobe signal.

10. The memory device of claim 7, wherein the calibration code generation circuit is configured to:
generate a synthetic test strobe signal and a clock strobe signal based on the calibration test mode signal and the calibrated clock signal; and
compare the synthetic test strobe signal and the clock strobe signal to generate the calibration code.

11. The memory device of claim 1, wherein the calibration code generation circuit comprises:
a synthetic test strobe signal generation circuit configured to generate a synthetic test strobe signal based on the calibration test mode signal and the calibrated clock signal;
a clock strobe signal generation circuit configured to generate a clock strobe signal based on the calibration test mode signal and the calibrated clock signal; and
a strobe signal comparison circuit configured to compare the synthetic test strobe signal and the clock strobe signal to generate the calibration code.

12. The memory device of claim 11, wherein the synthetic test strobe signal generation circuit is configured to:
latch the calibration test mode signal based on the calibrated clock signal to generate a plurality of test patterns; and
synthesize the plurality of test patterns to generate the synthetic test strobe signal.

13. The memory device of claim 12,
wherein the synthetic test strobe signal generation circuit generates first to fourth test patterns,
wherein a logic level of the first test pattern transitions from a logic low level to a logic high level and the first test pattern is driven by a PMOS transistor and NMOS transistor (PN) driver,
wherein a logic level of the second test pattern transitions from a logic low level to a logic high level and the second test pattern is driven by an NMOS transistor and NMOS transistor (NN) driver,
wherein a logic level of the third test pattern transitions from a logic high level to a logic low level and the third test pattern is driven by a PN driver, and
wherein a logic level of the fourth test pattern transitions from a logic high level to a logic low level and the fourth test pattern is driven by an NN driver.

14. The memory device of claim 11,
wherein the synthetic test strobe signal generation circuit generates first to fourth test patterns, and
wherein the synthetic test strobe signal generation circuit comprises:
a first test input latch configured to latch and output the calibration test mode signal based on the calibrated clock signal;
a second test input latch configured to latch and output an inverted signal of the calibration test mode signal based on the calibrated clock signal;
a first test driver implemented as a PN driver and configured to drive the first test pattern based on an output signal of the first test input latch;
a second test driver implemented as an NN driver and configured to drive the second test pattern based on the output signal of the first test input latch;
a third test driver implemented as a PN driver and configured to drive the third test pattern based on an output signal of the second test input latch; and
a fourth test driver implemented as an NN driver and configured to drive the fourth test pattern based on the output signal of the second test input latch.

15. The memory device of claim 14, wherein the synthetic test strobe signal generation circuit further comprises:
a first strobe line through which the first test pattern is transmitted as a first test strobe signal;
a second strobe line through which the second test pattern is transmitted as a second test strobe signal;
a third strobe line through which the third test pattern is transmitted as a third test strobe signal;
a fourth strobe line through which the fourth test pattern is transmitted as a fourth test strobe signal; and
a strobe signal synthesis circuit configured to generate the synthetic test strobe signal based on the first test strobe signal, the second test strobe signal, the third test strobe signal, and the fourth test strobe signal.

16. The memory device of claim 15, wherein the strobe signal synthesis circuit generates the synthetic test strobe signal including a logic level that transitions in synchronization with a latest logic level transition time among logic level transition times of the first test strobe signal, the second test strobe signal, the third test strobe signal, and the fourth test strobe signal.

17. The memory device of claim 11, wherein the clock strobe signal generation circuit is configured to:
delay the calibrated clock signal by a preset clock delay period to generate a delayed calibrated clock signal when the calibration test mode signal is activated; and
generate the clock strobe signal in synchronization with the delayed calibrated clock signal.

18. The memory device of claim 11, wherein the strobe signal comparison circuit is configured to:
delay the clock strobe signal sequentially by a unit delay period to generate a plurality of delayed strobe signals; and
latch the synthetic test strobe signal in synchronization with each of the plurality of delayed strobe signals to generate the calibration code.

19. The memory device of claim 11, wherein the strobe signal comparison circuit comprises:
a first strobe signal delay circuit configured to delay the clock strobe signal by a first unit delay period to generate a first delayed strobe signal;
a first calibration code latch circuit configured to latch the synthetic test strobe signal based on the first delayed strobe signal to output the synthetic test strobe signal as a first bit of the calibration code;
a second strobe signal delay circuit configured to delay the first delayed strobe signal by a second unit delay period to generate a second delayed strobe signal; and
a second calibration code latch circuit configured to latch the synthetic test strobe signal based on the second delayed strobe signal to output the synthetic test strobe signal as a second bit of the calibration code.

20. A memory system comprising a base die and a plurality of core dies disposed over an interposer,
wherein the base die comprises:
a first alignment circuit configured to generate a calibration code based on a calibration test mode signal and a calibrated clock signal, shift the calibration code based on a shifting test mode signal to generate a shifting code, encode the shifting code to generate an encoding code, and generate and transmit a transmission code based on the encoding code; and
a second alignment circuit configured to decode the transmission code to generate a decoded code, and calibrate a strobe signal based on the decoded code to generate a calibrated strobe signal.

21. The memory system of claim 20, wherein the first alignment circuit comprises:
a code shifting circuit configured to generate the shifting code; and
a code encoder configured to generate the encoding code.

22. The memory system of claim 20, wherein the code shifting circuit comprises:
a write code shifting circuit configured to shift the calibration code based on the shifting test mode signal to generate a write shifting code; and
a read code shifting circuit configured to shift the calibration code based on the shifting test mode signal to generate a read shifting code.

23. The memory system of claim 22, wherein the code encoder comprises:
a write code encoder configured to encode the write shifting code to generate an encoding write code; and
a read code encoder configured to encode the read shifting code to generate an encoding read code.

24. The memory system of claim 23,
wherein the write code encoder generates the encoding write code including fewer bits than bits included in the write shifting code, and
wherein the read code encoder generates the encoding read code including fewer bits than bits included in the read shifting code.

25. The memory system of claim 23, wherein the first alignment circuit further comprises:
a write transmission code selection circuit configured to select and output one of the encoding write code and a manual write code as a transmission write code based on a manual activation signal; and
a read transmission code selection circuit configured to select and output one of the encoding read code and a manual read code as a transmission read code based on the manual activation signal.

26. The memory system of claim 20,
wherein the second alignment circuit comprises a code decoder configured to generate the decoded code, and
wherein the code decoder generates the decoded code set to include the same number of bits as the calibration code.

27. The memory system of claim 26,
wherein the second alignment circuit further comprises a strobe signal calibration circuit,
wherein the code decoder comprises:
a write code decoder configured to decode a transmission write code to generate a decoded write code; and
a read code decoder configured to decode a transmission read code to generate a decoded read code, and
wherein the strobe signal calibration circuit comprises:
a write strobe signal calibration circuit configured to calibrate a write strobe signal based on the decoded write code to generate a calibrated write strobe signal; and
a read strobe signal calibration circuit configured to calibrate a read strobe signal based on the decoded read code to generate a calibrated read strobe signal.

28. A memory system configured by stacking a plurality of dies,
wherein one of the plurality of dies comprises:
a physical layer configured to control transmission of data, commands, and addresses using a plurality of channels between core dies and a processor; and
a serial-to-parallel conversion circuit configured to convert serial signals transmitted serially through the physical layer into parallel signals, align the parallel signals using a plurality of alignment circuits, and transmit the aligned parallel signals to a through via region,
wherein the plurality of alignment circuits comprise a first alignment circuit and a second alignment circuit,
wherein the first alignment circuit is configured to generate a calibration code based on a calibration test mode signal and a calibrated clock signal, shift the calibration code based on a shifting test mode signal to generate a shifting code, encode the shifting code to generate an encoding code, and generate and transmit a transmission code based on the encoding code, and
wherein the second alignment circuit is configured to decode the transmission code to generate a decoded code, and calibrate a strobe signal based on the decoded code to generate a calibrated strobe signal.
